(19) United States
(12) Patent Application Publication
(10) Pub. No.: US 2009/0000808 A1
(43) Pub. Date: Jan. 1, 2009

(54) Flexible Printed Circuit Board And Method Of Fabricating The Same

(76) Inventor: Te-Sheng Yang, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 11/772,216

(22) Filed: Jun. 30, 2007

(51) Int. Cl. H05K 3/28; H05K 1/00

(52) U.S. Cl. 174/254; 29/831

(57) ABSTRACT

Flexible printed circuit board and a method for fabricating the same are introduced. The circuit board of the flexible printed circuit board is mainly made up of a PI substrate having a circuit layer, and a polyimide layer press-bonded onto the PI substrate by using an adhesive layer. In order for the circuit layer to be conducting, the PI substrate is to be etched to precisely form a micro-through hole on the circuit layer, instead of punching the through hole onto the polyimide layer before it is press-bonded onto an existing PI substrate having a circuit layer as used in conventional method. As a result, the alignment of the through hole with respect to the circuit layer is more precise.

### BACKGROUND OF THE INVENTION

1. Field of the Invention

The present invention is generally related to a flexible printed circuit board and a method for fabricating the same, and in particular to a method of forming a micro-through hole on a circuit layer by etching a polyimide substrate.

2. The Prior Arts

A printed circuit board is formed such that the wiring pattern for coupling the electrical parts is to be “printed” onto a non-conductive board by using machining or surface treatment, whereby the electrical components can be mounted thereon. In other words, the printed circuit board is in reference to a substrate on which the electrical components are to be mounted.

Generally speaking, the copper foil of a traditional flexible circuit board is too thick, which leads to difficulty in making a thin enough circuit; and therefore, multi-layered boards have to be provided to meet the demands for the complicated circuit layout. If an additional polyimide (PI) layer is needed to add to an existing polyimide substrate having a circuit layer, the common method is to press-bond the polyimide layer onto the existing PI substrate having a circuit layer by using adhesive, during which when a through hole is required to be made at a designated location on the circuit layer, a die is utilized for punching a through hole onto the polyimide layer before it is pressed onto the PI substrate having a circuit layer.

However, if the patterns on the PI layer were required to be changed, other dies have to be fabricated, which thereby increases the fabrication cost. In addition, when the through hole is punched by a die, due to the difficult to control, the accuracy of the positioning of the through hole with respect to the circuit layer is very difficult to achieve. The etching technology, though may increase the accuracy of the positioning of the through hole with respect to the circuit layer, cannot etch the adhesive which is used during the fabrication process. Accordingly, the etching technology cannot make the micro-through hole, and therefore, the density for the circuit board cannot be enhanced. Besides, during the compression process, the heated melting glue formed by the adhesive by reason of pressure and temperature would flow onto the circuit layer of the PI board to affect the quality of the product.

### SUMMARY OF THE INVENTION

A primary objective is to provide a flexible printed circuit board and a method for fabricating the same. Instead of using the traditional method with the through hole punched onto a polyimide layer before the layer is compressed onto an existing PI substrate having a circuit layer, according to the present invention, a micro-through hole is precisely formed on the circuit layer by etching the PI board.

Based on the above goals, the circuit board of the flexible printed circuit board, according to the present invention, is mainly made up of a PI substrate having a circuit layer, and a polyimide layer compressed onto the existing PI substrate by using adhesive. In order for the circuit layer to be conducting, the PI substrate is to be etched to precisely form a micro-through hole on the circuit layer in accordance with the present invention, instead of using the traditional method with which the through hole is punched onto the polyimide layer before it is compressed onto an existing PI substrate having a circuit layer. As a result, the cost for making a die is saved; and the alignment of the through hole with respect to the circuit layer is more precise.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A-1D are a plurality of cross-sectional views showing the fabrication method of a flexible printed circuit board, according to an embodiment of the present invention.

### DETAILED DESCRIPTION OF THE PREFERRED EMBODIMENT

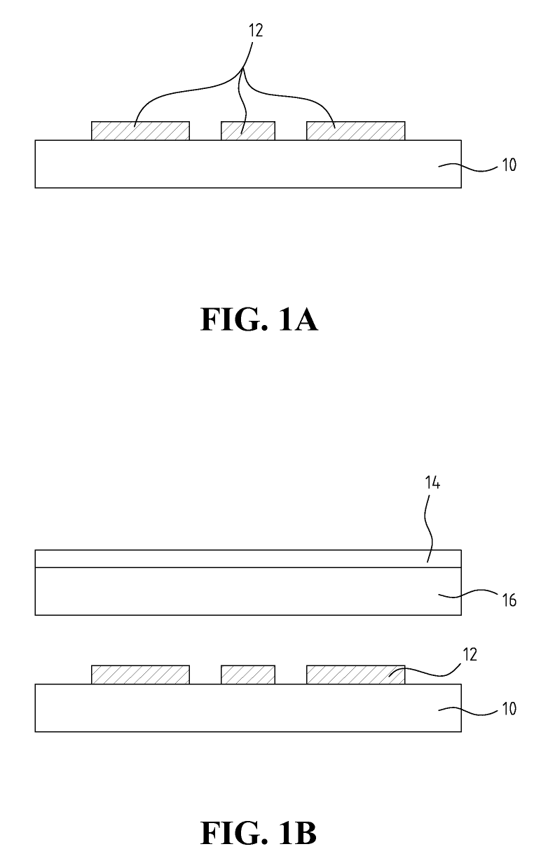

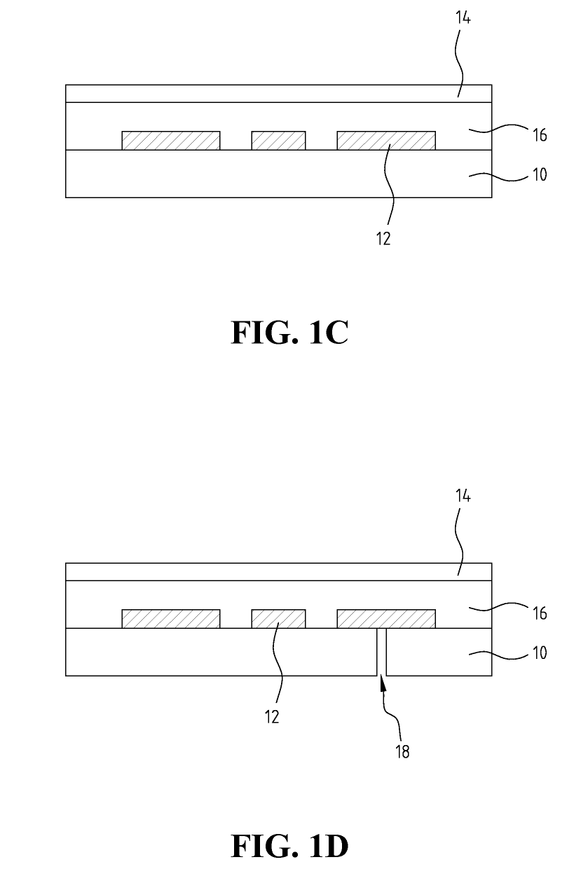

FIGS. 1A-1D are a plurality of cross-sectional views showing the fabrication method of a flexible printed circuit board, according to an embodiment of the present invention.

Referring to FIG. 1D, the flexible printed circuit board constructed in accordance with the present invention is mainly made up of a PI substrate 10 having a circuit layer, and a polyimide layer 14 is press-bonded onto the PI substrate 10 by using an adhesive layer 16. In order for the circuit layer 12 to be conducting electricity, according to the present invention, the PI substrate 10 is to be etched to precisely form a micro-through hole on the circuit layer 12, instead of using the traditional method with which a through hole is punched onto the polyimide layer 14 before it is press-bonded onto an existing PI substrate 10 having a circuit layer 12. As a result, the cost for making a die is saved, and the alignment of the through hole corresponding to the circuit layer is more precise.

The fabrication method according to the embodiment of the present invention share several similarities as the conventional fabrication method for making the flexible printed circuit board up to FIG. 1D. The main difference is that the traditional method uses a die with less precision for forming a through hole; whereas, according to the present invention, the PI substrate 10 is etched to form the micro-through hole 18 using any conventionally available higher precision etching technology. The following will further describe the fabrication method with accompanying drawings, according to the present invention.

Referring to FIG. 1A, a PI substrate 10 having a circuit layer 12 is first provided. Later, the polyimide layer 14 is prepared, and the adhesive layer 16 is coated onto the polyimide layer 14 as shown in FIG. 1B. Then the polyimide layer 14 is press-bonded onto the PI substrate 10 having a circuit layer 12 by means of the adhesive layer 16, as illustrated in FIG. 1C. Finally, the PI substrate 10 is etched until the circuit layer 12 is exposed, and the micro-through hole 18 is formed on the circuit layer 12. More importantly, the adhesive layer is very difficult to be etched; therefore, the micro-through hole 18 has to be etched at the surface where no adhesive layer 16 is coated.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A method for fabricating a flexible printed circuit board, comprising:
providing a polyimide substrate having a circuit layer;
press-bonding a polyimide layer onto the polyimide substrate having the circuit layer using an adhesive layer; and
etching the polyimide substrate until the circuit layer is to be exposed to form a micro-through hole therein.

2. A flexible printed circuit board, comprising:
a polyimide substrate, having a circuit layer, and a micro-through hole formed on the circuit layer;
a polyimide layer, press-bonded onto the polyimide substrate having a circuit layer using the adhesive layer, wherein the micro-through hole is formed by etching the polyimide substrate.
